(19) United States
(12) Patent Application Publication
(10) Pub. No.: US 2026/0354184 A1
(43) Pub. Date: Nov. 5, 2026

(54) POWER SEMICONDUCTOR MODULES AND RELATED METHODS

(71) Applicant: SEMICONDUCTOR COMPONENTS INDUSTRIES, LLC, Scottsdale, AZ (US)

(72) Inventors: Seungwon IM, Bucheon (KR); Chee Hiong CHEW, Seremban (MY); Dukyong LEE, Bucheon (KR); Sridhar Iyengar MUDNAKUD RAJAGOPALA, Singapore (SG)

(73) Assignee: SEMICONDUCTOR COMPONENTS INDUSTRIES, LLC, Scottsdale, AZ (US)

(21) Appl. No.: 19/197,143

(22) Filed: May 2, 2025

(51) Int. Cl. H10W 40/47; H10W 40/00; H10W 72/00; H10W 90/00

(52) U.S. Cl. CPC H10W 40/47; H10W 40/037; H10W 90/00; H10W 72/07331; H10W 90/736

(57) ABSTRACT

Implementations of a cooler for a power semiconductor device may include a top portion including a first largest planar surface configured for receiving one or more power semiconductor devices coupled thereon, the top portion having a second largest planar surface opposing the first largest planar surface, the second largest planar surface including a plurality of pin fins extending therefrom; and a bottom portion including a planar surface facing the plurality of pin fins. The length of each pin of the plurality of pin fins may be long enough to cause a tip of each pin to overtravel into a material of the planar surface when the top portion and bottom portion may be coupled together.

### BACKGROUND

### 1. Technical Field

Aspects of this document relate generally to cooling systems, such as systems for cooling semiconductor die during operation.

### 2. Background

Various semiconductor packages have been devised that allow for protection of a semiconductor die from humidity or electrostatic discharge. Other semiconductor package designs work to prevent damage to the semiconductor die from shock or vibration. Various other semiconductor packages allow for various electrical connections to be formed between the semiconductor die and a circuit board or motherboard to which the semiconductor packages are attached.

### SUMMARY

Implementations of a cooler for a power semiconductor device may include a top portion including a first largest planar surface configured for receiving one or more power semiconductor devices coupled thereon, the top portion having a second largest planar surface opposing the first largest planar surface, the second largest planar surface including a plurality of pin fins extending therefrom; and a bottom portion including a planar surface facing the plurality of pin fins. The length of each pin of the plurality of pin fins may be long enough to cause a tip of each pin to overtravel into a material of the planar surface when the top portion and bottom portion may be coupled together.

Implementations of a cooler for a power semiconductor device may include one, all, or any of the following:

The one or more power semiconductor devices may be coupled to the first largest planar surface through sintering.

Overtravel of the tip of each pin fin may prevent warpage of the top portion and the bottom portion during the sintering.

The tip of each pin fin of the plurality of pin fins may include a cone.

The tip of each pin fin of the plurality pin fins may include a conical frustum.

The conical frustum may have a smaller diameter at a base of the conical frustum than a diameter of a longest portion of each pin fin.

The distance of the overtravel of each pin fin may be a predetermined distance based on an average length of each pin fin.

The bottom portion further may include two ports configured to allow a coolant to enter and leave an enclosed space between the top portion and the bottom portion into which the plurality of pin fins extend.

Implementations of a cooler for a power semiconductor device may include a top portion with a first largest planar surface, the top portion having a second largest planar surface opposing the first largest planar surface, the second largest planar surface including a plurality of fins extending therefrom; and a bottom portion including a planar surface facing the plurality of fins. The length of each fin of the plurality of fins may be long enough to cause a tip of each fin to overtravel into a material of the planar surface when the top portion and bottom portion may be coupled together.

Implementations of a cooler for a power semiconductor device may include one, all, or any of the following:

One or more power semiconductor devices may be coupled to the first largest planar surface through sintering.

Overtravel of the tip of each fin may prevent warpage of the top portion and the bottom portion during the sintering.

The shape of a cross sectional shape of each fin of the plurality of fins may be one of a square, a rectangle, an ellipse, a triangle, a hexagon, or any closed shape.

The shape of a cross sectional shape of the tip each fin of the plurality of fins may be one of a square, a rectangle, an ellipse, a triangle, a hexagon, or any closed shape.

The distance of the overtravel of each fin may be a predetermined distance based on an average length of each fin of the plurality of fins.

The bottom portion further may include two ports configured to allow a coolant to enter and leave a space between the top portion and the bottom portion into which the plurality of fins extend.

Implementations of a method of assembling a power semiconductor module may include providing a top portion with a first largest planar surface, the top portion having a second largest planar surface opposing the first largest planar surface, the second largest planar surface including a plurality of fins extending therefrom; and coupling one or more semiconductor packages on the first largest planar surface using a sinter paste. The method may include fastening a bottom portion including a planar surface facing the plurality of fins; driving a tip of each fin into a material of the planar surface during the coupling of the top portion and the bottom portion an overtravel distance; and sintering the top portion, the bottom portion, and the one or more semiconductor packages.

Implementations of a method of assembling a power semiconductor module may include one, all, or any of the following:

The method may include performing X-ray inspection to determining a degree of warpage of the top portion and the bottom portion.

The method may include reducing the degree of warpage of the power semiconductor module through the overtravel distance of the tip of each fin.

The bottom portion may include two ports configured to receive a coolant that flows around the plurality of fins.

The method may include forming the plurality of fins on the second largest planar surface through one of machining or casting.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a side cross sectional view of an implementation of a power semiconductor module;

FIG. 2 is a detail cross sectional view of an implementation of a power semiconductor module;

FIG. 3 is a detail cross sectional view of an implementation of a power semiconductor module;

FIG. 4 is a detail view of two implementations of a pin fin;

FIG. 5 is a top view of an implementation of a top portion of a cooler;

FIG. 6 is a side view of an implementation of a top portion of a cooler;

FIG. 7 is an end view of an implementation of a top portion of a cooler;

FIG. 8 is a bottom view of an implementation of a top portion of a cooler showing various pin fins;

FIG. 9 is a detail view of the pin fins of FIG. 8;

FIG. 10 is a side view of an implementation of a bottom portion of a cooler;

FIG. 11 is an end view of an implementation of a bottom portion of a cooler;

FIG. 12 is a side cross sectional view of an implementation of a top portion coupled with an implementation of a bottom portion;

FIG. 13 is a detail view of the pin fins of the cooler implementation of FIG. 12;

FIG. 14 is an end see-through view of the cooler implementation of FIG. 12;

FIG. 15 is a perspective view of an implementation of a top portion with sinter paste portions applied to a first largest planar surface;

FIG. 16 is a perspective view of a bottom surface of an implementation of a bottom portion of a cooler;

FIG. 17 is a view of an implementation of a semiconductor package, a perspective top view of a cooler implementation plurality of semiconductor packages coupled over the sinter paste portions of FIG. 15, and a perspective bottom view of the cooler implementation;

FIG. 18 are various view of the cooler implementation of FIG. 17 following a sintering process.

### DESCRIPTION

This disclosure, its aspects and implementations, are not limited to the specific components, assembly procedures or method elements disclosed herein. Many additional components, assembly procedures and/or method elements known in the art consistent with the intended coolers for semiconductor devices will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such coolers for semiconductor devices, and implementing components and methods, consistent with the intended operation and methods.

Referring to FIG. 1, a side cross sectional view of an implementation of a cooler 2 for a semiconductor device is illustrated. The cooler 2 includes a top portion 4 and a bottom portion 6. While the use of the terms “top” and “bottom” are used for easier description in this document, the top portion is also the portion of the cooler 2 to which a plurality of semiconductor packages/devices 6 is attached, while the bottom portion 6 is the portion that faces and helps form an enclosure for coolant to flow around a plurality of pin fins 8. The coolant may be a liquid or a gas in various implementations.

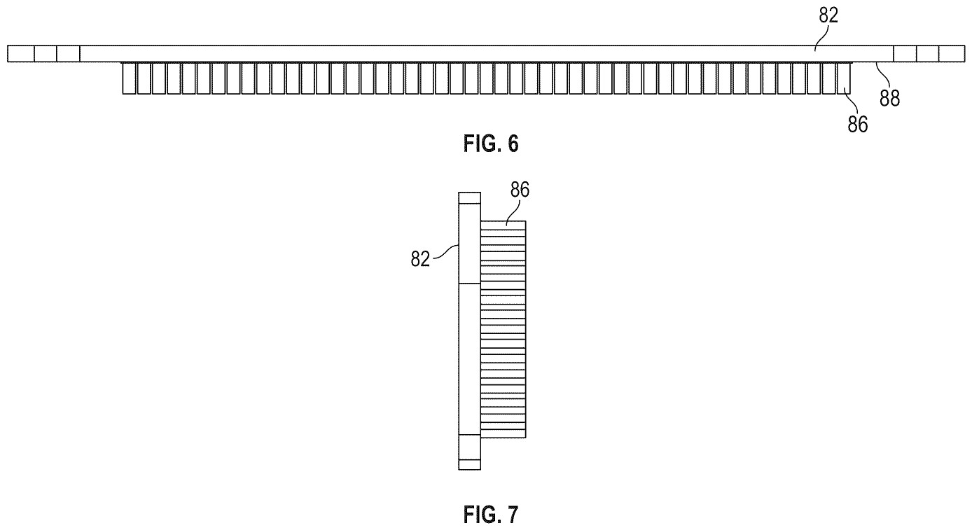

While the plurality of semiconductor packages 6 illustrated in FIG. 6 are power semiconductor packages containing various power semiconductor die, other types of semiconductor devices may be attached in packaged form to the top portion 4, including, by non-limiting example, metal oxide field effect transistors (MOSFETs), insulated gate bipolar transistors (IGBTs), diodes, rectifiers, thyristors, microprocessors, graphics processors, or any other semiconductor device type. The various semiconductor die included in the plurality of packages may be formed on/of any of a wide variety of semiconductor substrate types including, by non-limiting example, silicon, silicon carbide, gallium nitride, gallium arsenide, silicon on insulator, sapphire, ruby, or any other semiconductor material type. The various semiconductor packages may include a mold compound/electrically insulative encapsulant or may include various layers that are exposed through the mold compound/electrically insulative encapsulant. Various electrical connectors may be employed (pins, clips, wirebonds, etc.) and various leadframes and/or substrates may be included in the semiconductor packages. Embedded semiconductor die may be included in the various semiconductor package implementations. In some implementations, the semiconductor packages may all be the same, but in others, one or more of the semiconductor packages may be different either through structure, including different semiconductor die, or both.

FIG. 1 illustrates how heat generated during operation of the semiconductor packages is transferred using conductive heat transfer from the packages down through a sintered layer 10, through the thickness of the top portion 4, and down along a length of each of the pin fins 8. Convective heat transfer from the pin fins 8 then transfers the heat to the coolant as it flows through the enclosed space 12 between the top portion 4 and bottom portion 6. Because in various implementations the electrical connectors 14 of the plurality of semiconductor packages 6 take the form of pins/press-fit pins, the tolerance between the electrical connectors 14 and a pin receiver on a circuit or motherboard to which the cooler 2 is coupled is important. Where the plurality of semiconductor packages 6 is attached/coupled to the to portion 4 using sintering, it has been observed that the top portion, bottom portion, or both the top and bottom portion can warp an unpredictable degree during the high temperature process. This deformation of the cooler structure leads to different thermal performance for one or more of the plurality of semiconductor packages 6 attached to the top portion 4 of the cooler. After analysis, a main cause of the deformation/warping is because of observed variation in the length of each pin fin/fin of the plurality of pin fins/fins that are coupled to the bottom largest planar surface 16 of the top portion. FIG. 1 illustrates various pin fins/fins that have differing lengths.

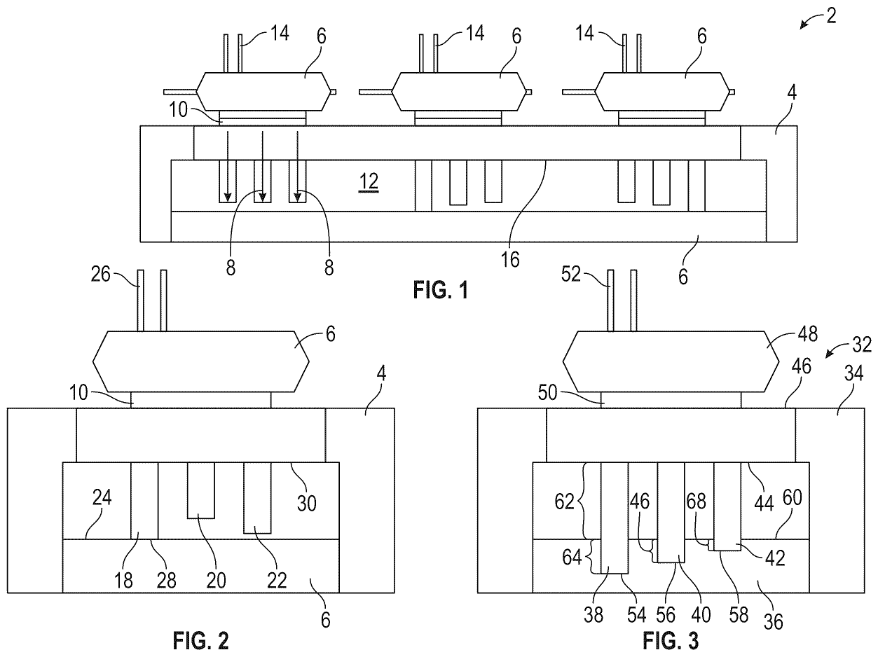

Referring to FIG. 2, a detail view of the semiconductor package 6 attached through sintering layer 10 to top portion 4 is illustrated. Here, three pin fins 18, 20, 22 are illustrated, each having a different length. Pin fin 20 is the shortest followed by pin fin 22. Neither of these pin fins reach the surface 24 of the bottom portion 6 that opposes the pin fins 18, 20, 22. Because of this remaining space between the ends of the pin fins 20, 22, during the sintering process, the top portion 4, bottom portion 6, or both the top portion and bottom portion are free to mechanically move relative to each other during the sintering process. The resulting warpage/displacement shifts the position of the electrical connectors 26 of the semiconductor package 6 which can cause an inability to insert the electrical connectors 26 into the corresponding receiver or socket. If the pin fins 20, 22 were the same length as pin fin 18 which has a tip 28 that just touches the surface 24, the pin fins 18, 20, 22 would collectively mechanically reinforce the top portion 4 and bottom portion 6 and prevent mechanical movement of the portion(s) relative to each other during sintering. Achieving this kind of dimensional tolerance for all or even substantially all of the pin fins across the entire second largest planar surface 30 of the top portion 4 is challenging. This is particularly so where the various pin fins are screwed, welded, soldered, friction fit, or otherwise mechanically coupled to the second largest planar surface 30. Even where the pin fins are formed integrally from the material of the top portion through a machining (milling, etc.) process, achieving the degree of dimensional tolerance for each pin fin across the entire largest planar surface is challenging. Machining all of the pin fins also is a time consuming process that can be more expensive than simple mechanically coupled pin fins. Finally, where fin structures other than pin fins are utilized the ability to control dimensional tolerance may be further reduced. Examples of alternative fin structures that could be utilized in various implementations include, by non-limiting example, row structures, column structures, linked structures, alternating fin structures, and other three-dimensional structures that can extend away from the second largest planar surface 30.

Because of the challenge presented by the dimensional tolerance variation of the pin fins 18, 20, 22, attempting to rely on these pin fins to help prevent mechanical deformation of the cooler during the sintering process is not likely to produce consistent results. A different approach is illustrated in FIG. 3. Here, a detail view of another implementation of a cooler 32 that includes top portion 34 coupled to bottom portion 36. Pin fins 38, 40, 42 extend from second largest planar surface 44 that opposes first largest planar surface 46 to which semiconductor package 48 is coupled through sintering layer 50. Semiconductor package 48 also includes electrical connectors 52 that extend away from the semiconductor package.

In the cooler implementation 34 illustrated in FIG. 3, the pin fins 38, 40, 42 are still different lengths, reflecting that they were manufactured with a process that has dimensional variation. However, the tips 54, 56, 58 of each of the pin fins 38, 40, 42 extend past the planar surface 60 of the bottom portion 36 into the material of the bottom portion 36. This is because the design/nominal length of each of the pin fins 38, 40, 42 was set to be longer than the width 62 of the enclosure between the top portions 34 and bottom portions 36. Because of this, despite the normal dimensional variation involved in the particular process of manufacturing the pin fins 38, 40, 42, the tips 54, 56, 58 of all of the pins will still contact and drive into the material of the bottom portion 36. The distance the tips 54, 56, 58 of the pin fins travel into, or overtravel into, the material of the bottom portion 36 is referred to as an overtravel or overtravel distance 64, 66, 68 herein. This ability to rely on overtravel of the pin fin means that a desired average overtravel distance for each pin fin is a predetermined distance that is based on an average length of each pin fin. This average length the pin fins may be calculated using actual measurements of pin fins as manufactured or through a dimensional tolerance buildup analysis based on the particular manufacturing and assembly process of the pin fins.

In some cooler implementations, the shape/cross sectional shape of each pin fin 38, 40, 42 remains the same along its entire length (constant cross section) and the tip of the pin fin then overtravels into the material of the bottom portion a distance corresponding with how the length of each pin fin is longer than the width 62. In such implementations, while the tips 54, 56, 58 may penetrate into the material, in some implementations, because the end of the tips are substantially flat, the material of one or more of the pin fins 38, 40, 42 may smash or crush against the surface 60. This generally would be expected to provide similar mechanical reinforcement against warpage but may tend to increase stresses between the top portion and bottom portion as the cooler heats and cools because of the lack of a uniform mechanical interface between the pin fins 38, 40, 42 and the material of the bottom portion 36. Such a design is illustrated in the cooler 32 of FIG. 3.

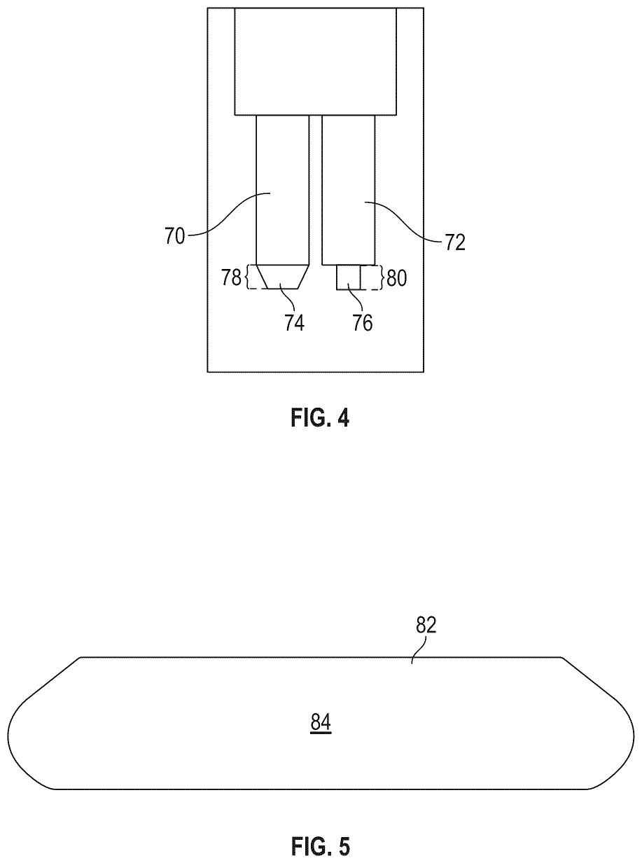

However, in other implementations, to aid in the smoother mechanical process of achieving overtravel of the pin fins 38, 40, 42 during coupling of the top portion 34 and bottom portion 36, the shape of the tips 54, 56, 58 may be altered to help ensure that they penetrate the material of the bottom portion. Referring to FIG. 4, implementations of two pin fins 70, 72 that include tips 74, 76 that have a different cross sectional shape(s) than the main body of the pin fins 70, 72. Tip 74 has the shape of a conical frustrum (truncated cone) where the cross section of the tip portion of the pin fin 70 varies linearly along the length 78 of the tip portion of the pin fin 70. Tip 76 illustrates a different design where the shape of the tip has a constant or substantially constant cross sectional shape along the length 80 of the tip portion of the pin fin 72. The cross sectional shape of the tip 76 is smaller in size than the cross sectional shape of the main portion of the pin fin 76. This step down in size can assist with the tip portion penetrating the material of the bottom portion or securely smashing against the surface of the bottom portion to provide the desired mechanical stability.

A wide variety of shapes for the tips of the pin fins may be employed in various implementations, including, by non-limiting example, conical, pyramidal, cylindrical, ellipsoidal, cuboidal, spherical, or any other regular or irregular closed shape. The cross sectional shape of the pin fins in various implementations may be, by non-limiting example, a square, a rectangle, an ellipse, a triangle, a hexagon, or any other closed shape. For the tips of the pin fins, a cross sectional shape of the tip portion may be, by non-limiting example, a square, a rectangle, an ellipse, a triangle, a hexagon, or any other closed shape. The cross section of the tip portion of the pin fin may also vary linearly or non-linearly along a length of the tip in various implementations as well. A wide variety of combinations of cross sectional shapes of pin fins, tips, and tip portions may be constructed using the principles disclosed herein.

In various implementations, in combination with the particular shapes of the pin fins/fins and tips thereof, the materials of the pin fins/fins and the bottom portion may be selected to assist with overtravel of the pin fins into the bottom portion. For example, in some implementations, the same metal material with same material properties may be employed for the pin fins and for the bottom portion, such as, by non-limiting example, aluminum and aluminum or copper and copper. In other implementations, the same metal or metal alloy may be employed for the pin fins as for the bottom portion but the pin fins are made of a mechanically stronger version than the metal/metal alloy of the bottom portion. For example, a high strength aluminum would be used for the pin fins while a lower strength aluminum would be used for the material of the bottom portion. In yet other implementations, different metals/metal alloys may be used for the pin fins and for the bottom portion to achieve the desired contrast in mechanical material properties. For example, the pin fins may be made of copper while the bottom portion is made of aluminum and vice versa. Those of ordinary skill will be able to use the principles disclosed herein to select the appropriate combination of materials for the pin fins and the bottom portion to achieve the desired overtravel of the pin fins.

The particular shapes of the top portion and bottom portion of the cooler are generally driven by the dimensions and desired configuration of the semiconductor packages along with any constraints related to the mounting location. In some implementations, the cooler and semiconductor packages form a power semiconductor module which collectively performs a specific function. For example, in some implementations the power semiconductor module may function as a traction inverter that is liquid cooled. FIG. 5 is a top view of an implementation of a top portion 82 which shows that the top portion may be symmetric about one axis, but not two axes in particular implementations. In this view, a first largest planar surface 84 is illustrated to which one or more semiconductor packages will be attached.

FIG. 6 is a side view of the top portion 82 that shows the plurality of pin fins 86 extending from second largest planar surface 88. While the array of pin fins 86 in the implementation of FIG. 6 is illustrated as being uniformly distributed inside the perimeter of the enclosure that will be formed when the bottom portion is attached, in other implementations, the pin fins may be centered or otherwise distributed just around the mounting/coupling locations of the semiconductor package(s) forming gaps in the array. Also, the array of pin fins may be arranged in a non-uniform pattern, but may be concentrated near the mounting/coupling locations of the semiconductor packages. In yet other implementations, a random pattern may be used for the array of pin fins to achieve a desired heat transfer coefficient/transport profile. FIG. 7 is an end-on view of the top portion 82 and the array of pin fins 86. Note that in this view, the pin fins appear narrower because the pin fins in this implementation do not have a uniform cross sectional shape like a square, circle, or triangle, but are ellipses.

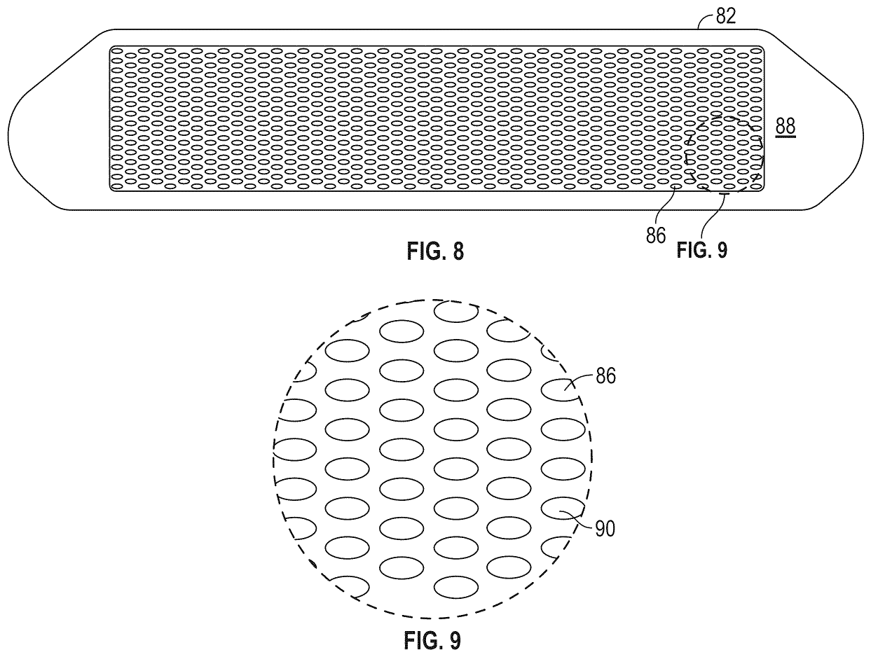

FIG. 8 is a bottom view of the second largest planar surface 88 of the top portion 82. In this view, the alternating pattern of the pin fins 86 is organized in rows along the largest dimension of the top portion. While this alternating row pattern is used, any of a wide variety of other regular, irregular, targeted, or random patterns could be employed for the various pin fin arrays in various implementations. FIG. 9 shows a detail view of the pin fin array in FIG. 8 which shows the cross sectional shape of each of the pin fins 86 because the tips 90 of each of the pin fins 86 are flat and do not include any of the previously mentioned three dimensional shapes or cross sectional shapes. In this implementation, the cross sectional shape of the pin fins is an oval or ellipse.

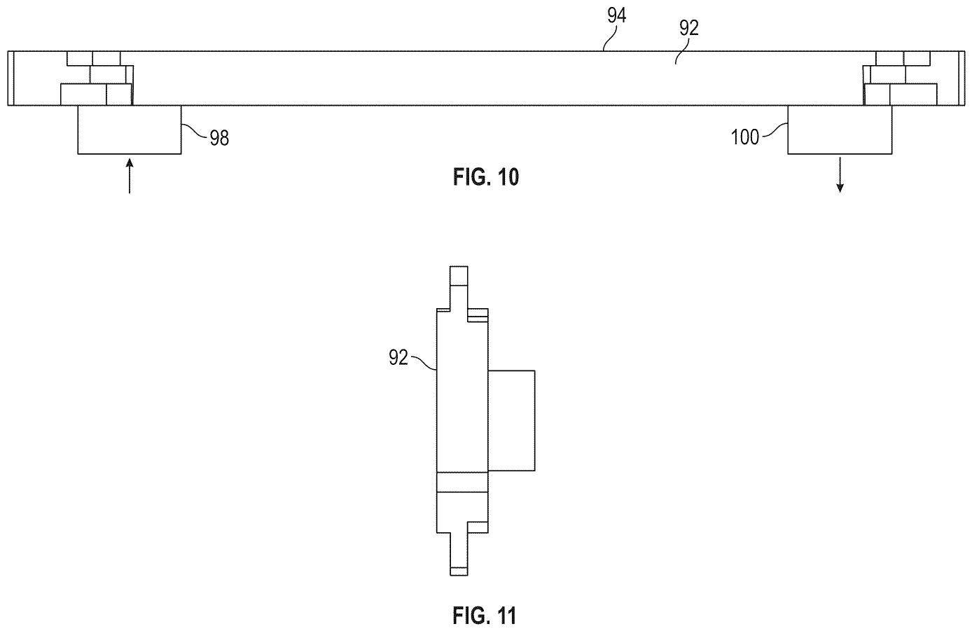

Referring to FIG. 10, an implementation of a bottom portion 92 is illustrated. In this implementation, the body portion includes a cavity 94 which includes a recessed surface that faces the array of pin fins from the top portion 82 implementation illustrated in FIGS. 6-9. The cavity 94 receives the pins and forms the remaining surfaces that form an enclosure in which coolant 96 flows into the enclosure through inlet 98, around the array of pin fins and then out through outlet 100. Each of the inlet 98 and the outlet 100 is designed so that a particular hose or other mechanism for delivering coolant thereto may be fixedly coupled with the structure of the outer portions of the inlet 98 and outlet 100. FIG. 11 is an end-in view of the bottom portion 92 which shows that, in this implementation, the inlet 98 and outlet 100 are arranged in a straight line aligned with the longest dimension of the bottom portion. The inlet and outlet in various implementations may take on many different shapes and locations depending on how the power semiconductor module will be attached to the coolant lines and installed.

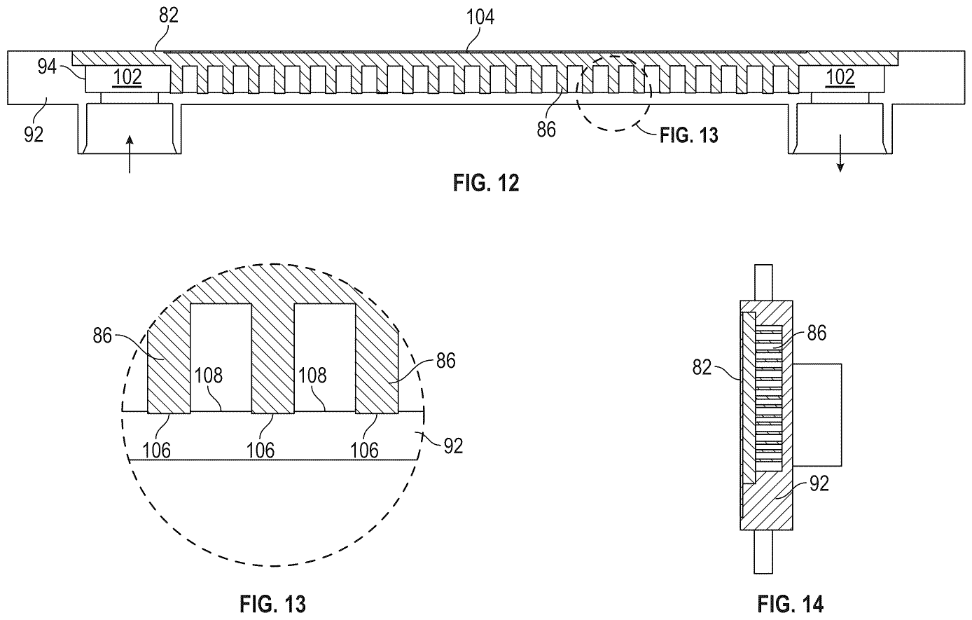

Referring to FIG. 12, the top portion 82 is illustrated when fully fixedly coupled with the bottom portion 92. As illustrated, the cavity 94 receives the array of pin fins 86 therein and forms enclosure 102 into which coolant flows in and out around the array. In this cross sectional view, a recess 104 in the first largest planar surface 104 of the top portion 82 is illustrated which is designed to assist with placement and holding of the semiconductor package(s) during a sintering bonding process. The top portion 82 and bottom portion 92 may be coupled using a wide variety of methods designed to achieve a fixed coupling relationship including, by non-limiting example, screwing, bolting, clamping, welding, soldering, or any other method of fixedly retaining the portions together and forming a coolant-tight seal. In some implementations one or more o-rings, gaskets, or other sealing structures/systems may be employed to ensure coolant does not leak from the joints between the top portion 82 and the bottom portion 92.

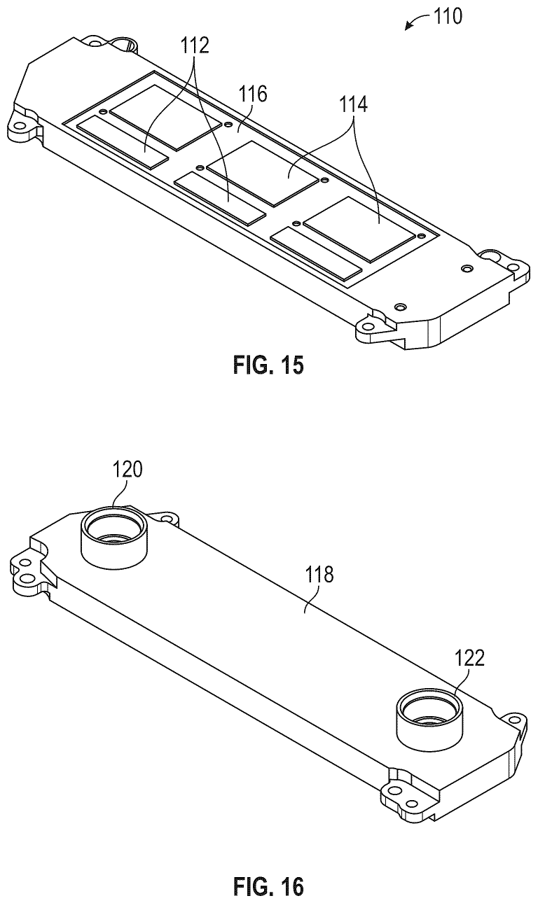

FIG. 13 is a detail view of the array of pin fins 86 from FIG. 12 and shows how each pin fin 86 is embedded/inserted/overtraveled into the material of the bottom portion 92 due to the length of each pin fin being longer than the width of the enclosure 102. Here the tips 106 of each of the pin fins 86 rest below the surface 108 of the bottom portion 92 due to the overtravel of each pin fin 86 into the material of the bottom portion 92. Note that the desired mechanical stabilization from the overtravel of the pin fins 86 can be achieved without the pin fins needing to travel a long distance into the material of the bottom portion 92 relative to the length of each of the pin fins 86. FIG. 15 is a see through end-on view of the top portion 82 and bottom portion 92 coupled together showing the orientation of the pin fins 86 relative to the coolant.

The various coolers and power semiconductor modules disclosed herein may be constructed using various implementations of a method of assembling a power semiconductor module. Referring to FIG. 15, an implementation of a top portion 110 is illustrated in a perspective view with portions of sintering paste 112, 114 in the recess 116. The sintering paste may be applied using a wide variety of techniques including, by non-limiting example, screen printing, dispensing, stencil printing, or any other technique that achieves a layer of a desired uniform height in a desired area. In some implementations, following the application of the sinter paste, a drying operation/process may be employed to help stabilize the sintering paste portions 112, 114 so they are ready for application of semiconductor packages thereon. In some implementations the sinter paste may include silver. In FIG. 15, the top portion 110 is illustrated coupled into bottom portion 118 which is illustrated in FIG. 16. As part of the coupling, creating the desired overtravel of the pins into the material of the bottom portion 118 has already been completed. FIG. 16 shows the corresponding bottom portion 118 in a perspective view of a bottom view/surface showing shows the inlet 120, 122 for the coolant.

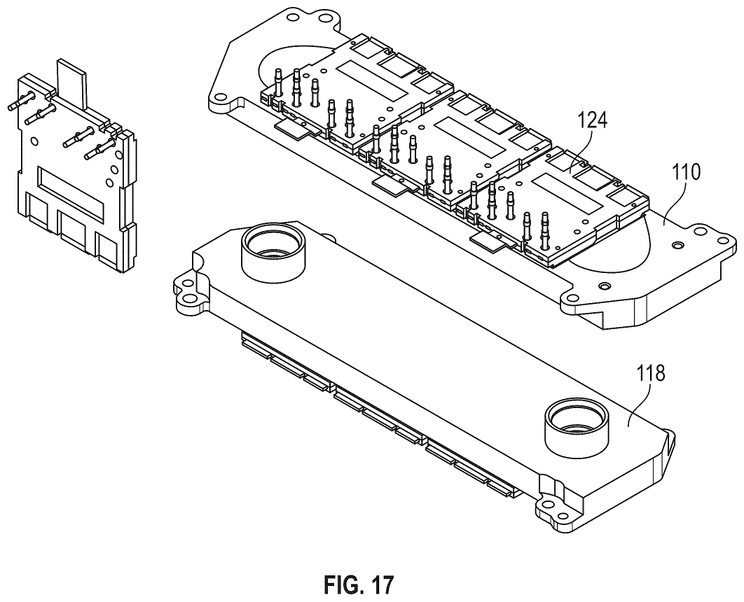

Referring to FIG. 17, the top portion 110 is illustrated following placement of semiconductor packages 124 onto the sintering paste 112, 114. In this implementation, the semiconductor packages 124 each include press fit pins 126 that extend upwardly therefrom. Once the semiconductor packages 124 have been placed therein, the top portion 110 and bottom portion 118 is now ready for a sintering operation to be carried out which forms a bond between the semiconductor packages 124 and the material of the top portion 110 of the cooler. Any of a wide variety of sintering processes may be utilized in various implementations consistent with the particular sintering system/materials used to form the bond between the particular material of the semiconductor packages and the top portion 110. FIG. 17 also shows a bottom view of the bottom portion 118 cooler showing the location of the semiconductor packages 124 after placement on the top portion 110.

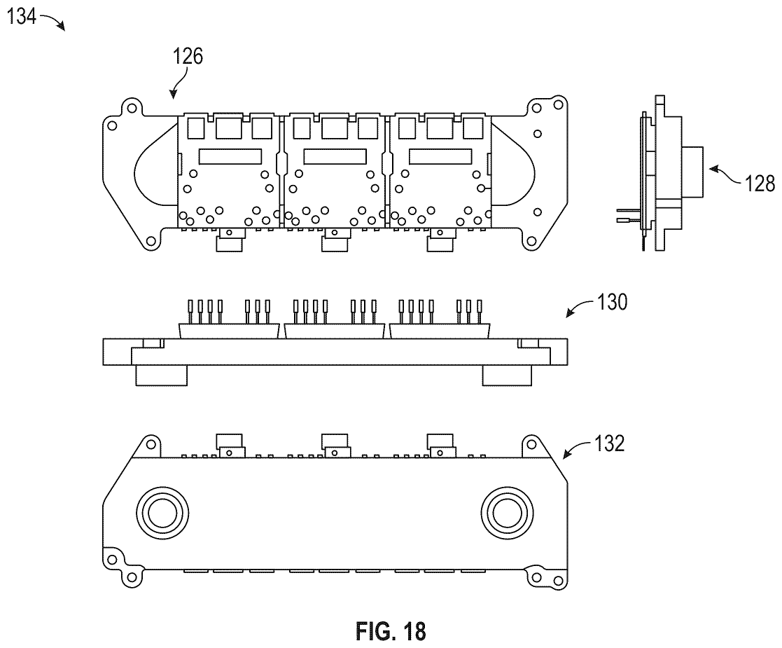

Referring to FIG. 18, four different views of the cooler are illustrated following completion of the sintering operation (top down 126, end-on 128, side 130, and bottom 132). These views illustrate how, after the sintering is completed, the use of the pin fins ensures that mechanical displacements and/or warpage are minimized/eliminated to allow the pins and other electrical connectors to remain in the desired locations. At this point, the power semiconductor module 134 is ready for assembly with the coolant lines and sockets/receivers at the point of use.

In places where the description above refers to particular implementations of coolers for semiconductor devices and implementing components, sub-components, methods and sub-methods, it should be readily apparent that a number of modifications may be made without departing from the spirit thereof and that these implementations, implementing components, sub-components, methods and sub-methods may be applied to other coolers for semiconductor devices.

What is claimed is:

1. A cooler for a power semiconductor device, the cooler comprising:
a top portion comprising a first largest planar surface configured for receiving one or more power semiconductor devices coupled thereon, the top portion having a second largest planar surface opposing the first largest planar surface, the second largest planar surface comprising a plurality of pin fins extending therefrom; and
a bottom portion comprising a planar surface facing the plurality of pin fins;
wherein a length of each pin of the plurality of pin fins is long enough to cause a tip of each pin to overtravel into a material of the planar surface when the top portion and bottom portion are coupled together.

2. The cooler of claim 1, wherein the one or more power semiconductor devices are coupled to the first largest planar surface through sintering.

3. The cooler of claim 2, wherein overtravel of the tip of each pin fin prevents warpage of the top portion and the bottom portion during the sintering.

4. The cooler of claim 1, wherein the tip of each pin fin of the plurality of pin fins comprises a cone.

5. The cooler of claim 1, wherein the tip of each pin fin of the plurality pin fins comprises a conical frustum.

6. The cooler of claim 5, wherein the conical frustum has a smaller diameter at a base of the conical frustum than a diameter of a longest portion of each pin fin.

7. The cooler of claim 1, wherein a distance of the overtravel of each pin fin is a predetermined distance based on an average length of each pin fin.

8. The cooler of claim 1, wherein the bottom portion further comprises two ports configured to allow a coolant to enter and leave an enclosed space between the top portion and the bottom portion into which the plurality of pin fins extend.

9. A cooler for a power semiconductor device, the cooler comprising:
a top portion with a first largest planar surface, the top portion having a second largest planar surface opposing the first largest planar surface, the second largest planar surface comprising a plurality of fins extending therefrom; and
a bottom portion comprising a planar surface facing the plurality of fins;
wherein a length of each fin of the plurality of fins is long enough to cause a tip of each fin to overtravel into a material of the planar surface when the top portion and bottom portion are coupled together.

10. The cooler of claim 9, wherein one or more power semiconductor devices are coupled to the first largest planar surface through sintering.

11. The cooler of claim 10, wherein overtravel of the tip of each fin prevents warpage of the top portion and the bottom portion during the sintering.

12. The cooler of claim 9, wherein a shape of a cross sectional shape of each fin of the plurality of fins is one of a square, a rectangle, an ellipse, a triangle, a hexagon, or any closed shape.

13. The cooler of claim 9, wherein a shape of a cross sectional shape of the tip each fin of the plurality of fins is one of a square, a rectangle, an ellipse, a triangle, a hexagon, or any closed shape.

14. The cooler of claim 9, wherein a distance of the overtravel of each fin is a predetermined distance based on an average length of each fin of the plurality of fins.

15. The cooler of claim 9, wherein the bottom portion further comprises two ports configured to allow a coolant to enter and leave a space between the top portion and the bottom portion into which the plurality of fins extend.

16. A method of assembling a power semiconductor module, the method comprising:
providing a top portion with a first largest planar surface, the top portion having a second largest planar surface opposing the first largest planar surface, the second largest planar surface comprising a plurality of fins extending therefrom;
coupling one or more semiconductor packages on the first largest planar surface using a sinter paste;
fastening a bottom portion comprising a planar surface facing the plurality of fins;
driving a tip of each fin into a material of the planar surface during the coupling of the top portion and the bottom portion an overtravel distance; and
sintering the top portion, the bottom portion, and the one or more semiconductor packages.

17. The method of claim 16, further comprising performing X-ray inspection to determining a degree of warpage of the top portion and the bottom portion.

18. The method of claim 17, further comprising reducing the degree of warpage of the power semiconductor module through the overtravel distance of the tip of each fin.

19. The method of claim 16, wherein the bottom portion comprises two ports configured to receive a coolant that flows around the plurality of fins.

20. The method of claim 16, further comprising forming the plurality of fins on the second largest planar surface through one of machining or casting.
